(19) United States
(12) Patent Application Publication
(10) Pub. No.: US 2018/0124930 A1
(43) Pub. Date: May 3, 2018

(54) Interactive Cabinetry Door for Use with a Cabinet Base

(71) Applicant: Michael Sisson, Tucson, AZ (US)

(72) Inventor: Michael Sisson, Tucson, AZ (US)

(21) Appl. No.: 15/339,441

(22) Filed: Oct. 31, 2016

(51) Int. Cl. H05K 5/00; H05K 5/02; H05K 1/18

(52) U.S. Cl. CPC H05K 5/0017; H05K 5/023; H05K 2201/10128; H05K 1/18; H05K 5/0204

(57) ABSTRACT

An interactive cabinet door for use with a cabinet base. The cabinet door includes a protective glass cover made from alkali-aluminosilicate, an electronic display adhesively coupled with the protective glass cover, a Printed Circuit Board (PCB) substrate electronically and adhesively coupled with the electronic display, a support frame surrounding the protective glass cover, the electronic display, and the PCB substrate, multiple support brackets fixed to the support frame along a peripheral back side of the support frame and mountable with the cabinet base, and a handle fixed to the support frame along a peripheral front side of the support frame.

### TECHNICAL FIELD

The present disclosure relates generally to household cabinets and, more specifically, to cabinet doors that utilizes a durable protective glass in combination with an electronic display substrate.

### BACKGROUND

Communication devices have become an integral part of society and most people today, young and old, must have a communication device or otherwise be digitally connected at almost all times. Consumers almost always have access to digital media either through smart phones, smart watches, tablets, televisions, and home computers. As the technology for these devices becomes cheaper, new uses of these devices are constantly evolving. A prime example is home interactive control and communication systems which recently have began to evolve in a more integrated way the aforementioned communications devices.

These systems can be anything from home entertainment systems, home security and monitoring systems, and home resource monitoring and control systems, e.g. electricity or other utilities. Some of the intelligent systems on the market today include the Ring® video doorbell that allows a home owner to monitor anyone that comes to their door to view who is at their door, either viewing remotely or locally. The Lyric® T5 Wi-Fi thermostat controls room temperature based on the user's location and allows remote control of the thermostat. A particular interesting product is the Amazon Echo® which allows a consumer to play Internet music channels, connect with other Internet websites, control lights, switches, thermostats, and other network connected home appliances using only voice commands.

As these technologies evolve, it is only reasonable to assume more integration with home appliances and more consumer interactive control, e.g. using means beyond just the consumer's smart device, smart watch, television, tablet, and home computer. A common feature of many of these smart phones, smart watches, and tablets is the use of a type of toughened glass known by one brand as Gorilla® Glass manufactured by Corning®, although there are other competitive brands. This type of glass is often used as a protective layer to the more sensitive electronics of these products because of its shock absorbent and shatter resistant properties. As such, these types of devices can be handled by a consumer and withstand impacts, e.g. when dropped, that may otherwise damage the device if not for the use of this product. Televisions screens do not traditional deploy the use of this product because televisions are not subjected to the same types of use as the smart phone, e.g. However, as previously mentioned and as the integration of these devices become more prevalent, especially with home automation and interactive communication systems, there will become a need for the use of these systems as they have not been used before and traditional applications may not be adequate.

As such, there is a need for a new type of display screens and accompanying support apparatus' that can be effectively used with home automation and interactive communication systems.

### SUMMARY

It is an object of the invention to provide a cabinet door that is made from an electronic digital display screen and PCB substrate, protective glass cover and support apparatus for use with home or office cabinets.

In an embodiment, the cabinet door includes an electronic display, a protective glass cover made from alkali-aluminosilicate, a Printed Circuit Board (PCB) substrate, a support frame, multiple support brackets, and a handle. In this embodiment, the electronic display and protective glass cover are adhesively coupled, or i.e. assembled, using an epoxy adhesive. Further in this embodiment, the electronic display and PCB substrate are communicable coupled and adhesively coupled using an epoxy adhesive. Additionally in this embodiment, the support frame surrounds and houses an assembled protective glass cover and electronic display, and the PCB substrate. The support frame further includes a multiple support brackets, such as hinges, mounted along a peripheral back side of the support frame for mounting with a cabinet base. The support frame further includes a handle mounted along a peripheral front side of the support frame.

These and other aspects, objects, features and advantages of the example embodiment will become apparent to those having ordinary skill in the art upon consideration of the following detailed description of illustrated example embodiments.

### BRIEF DESCRIPTION OF THE DRAWINGS

FIG. 1 is a perspective view of a interactive cabinet door for use with cabinet base according to an embodiment of the invention.

FIG. 2 is a perspective backside view of the assembled interactive cabinet door for use with a cabinet base according to an embodiment of the invention.

FIG. 3 is an exemplary view of a cabinet base system that utilizes interactive cabinet doors.

### DETAILED DESCRIPTION

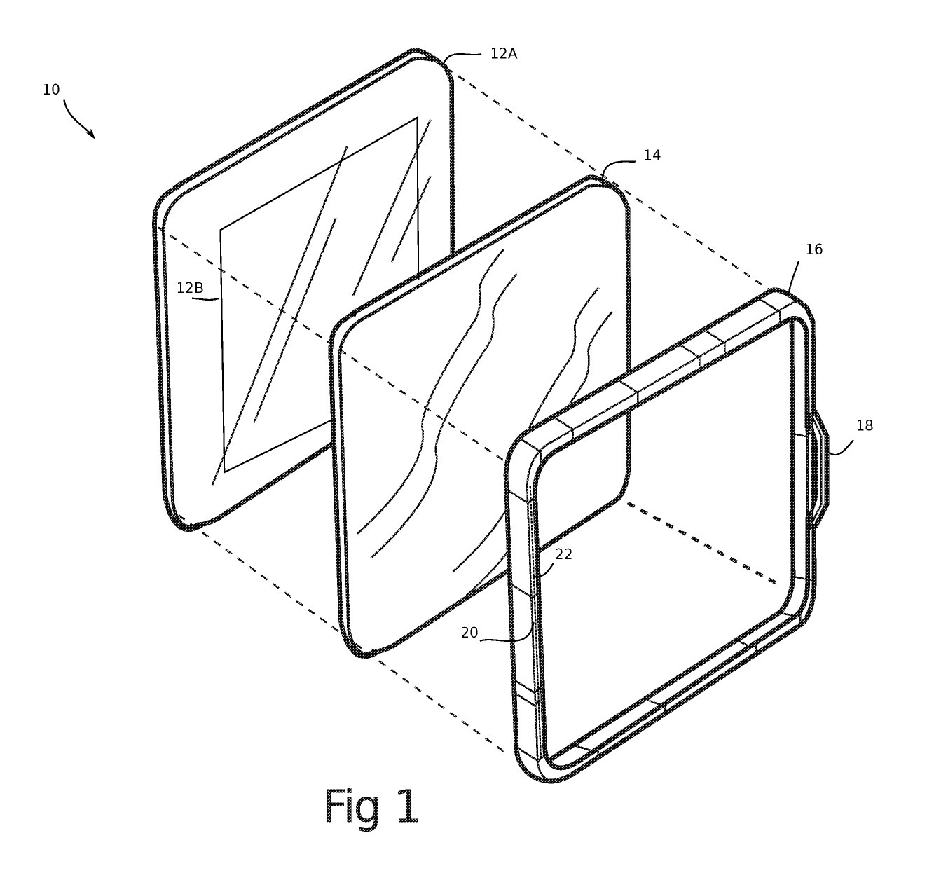

Referring now to FIG. 1, an interactive cabinet door for use with a cabinet base is illustrated and denoted generally as 10. The interactive cabinet door 10 includes a Printed Circuit Board (PCB) substrate 12A and display screen 12B. The PCB substrate 12A is an electronic communications apparatus capable of communicating electronic signals from another source, such as a central application server, over a communications interface, such as a wireless Wi-Fi interface, and interfacing the received data with the display screen 12B. The display screen 12B is a Liquid Crystal Display (LCD), e.g. a plasma display screen, a Light Emitting Display (LCD) screen, or an Organic Light Emitting Display (OLED) screen, for displaying digital images and information from PCB substrate 12 received from the other source. The cabinet door 10 further includes a protective glass cover 14 adhesively coupled with display screen 12B and, possibly, with the PCB substrate 12A. The interactive cabinet door 10 also further includes a support frame 16 surrounding the protective glass cover 14, the electronic display 12B and the PCB substrate 12A. The support frame 16 further includes a handle fixed to the support frame along a peripheral front side of the support frame 16, e.g. fixed to the support frame 16 using an adhesive or physically using screws or rivets.

The PCB substrate 12A and display screen 12B may be electronically and adhesively coupled together in order to provide electronic communications of information and images and produce a stabilized assembly. The protective glass cover 14 is made from a durable shock absorbent and shatter resistant glass, such as alkali-aluminosilicate. The protective glass cover 14 may be adhesively coupled, e.g. using an epoxy cement, to the display screen 12 and the PCB substrate 12A, although it may be enough that the protective glass cover 14 is only adhesively coupled with the display screen 12B. The support frame 16 surrounds the protective glass cover 14 and PCB substrate 12A. The support frame 16 may be further adhesively coupled with the glass cover 14 and PCB substrate 12A. The support frame 16 includes a front peripheral sidewall 20 where the handle 18 is mounted. The handle 18 can be mounted using an adhesive or fixed to the sidewall using screws or rivets. It should also be understood that the sidewall portion 20 may interiorly include a spacer and divider section 22 between the edges of the protective glass cover 14 and PCB substrate 12A and inner walls of the support frame 16. The spacer and divider section being useful for mounting needed and usable components, such as the handle 18, and securely positioning the protective glass cover 14 and PCB substrate 12A. More succinctly stated, the space section would provide support to the PCB substrate 12A and protective glass cover 14, e.g. using padding, to minimize or eliminate movement and the divider section would allow other components, such as the handle 18, to be properly secured to the support frame 16.

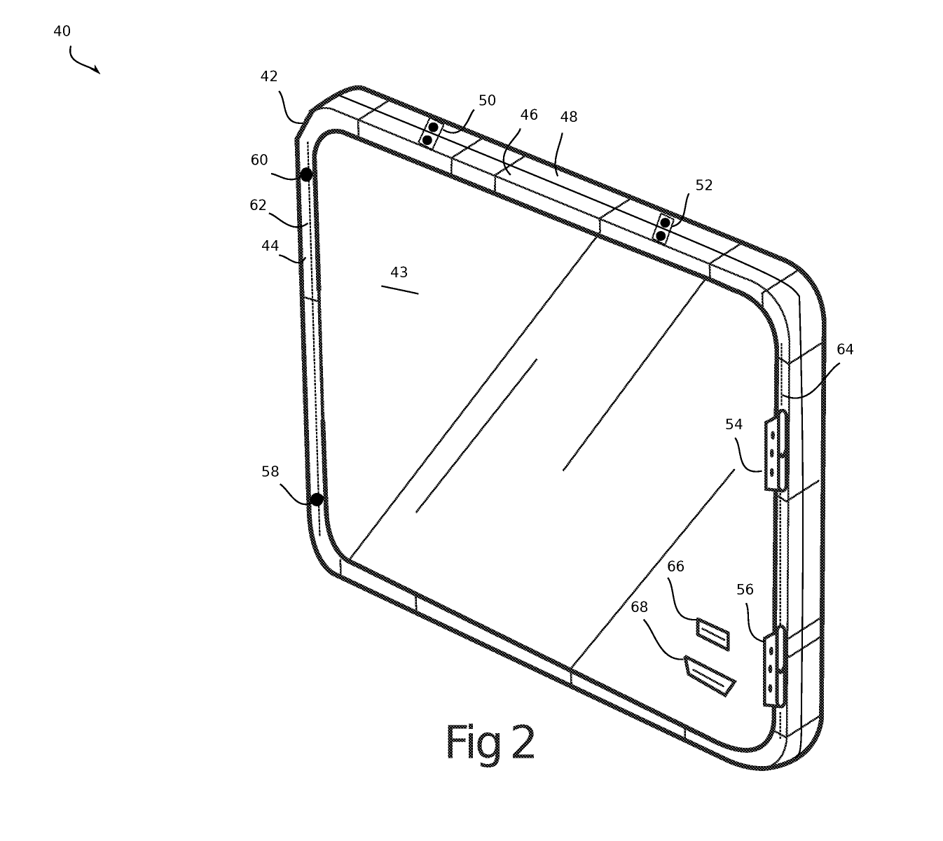

Referring now to FIG. 2, illustrated is backside view of the assembled interactive cabinet door for use with a cabinet base denoted generally as 40. The cabinet door 40 includes a support frame 42, and assembled screen 43 that includes a PCB substrate, display screen, and protective glass cover, and a sidewall section 44 of the support frame. The cabinet door may, optionally, also include a back support frame 46 and a front support frame 48 that can be coupled together in order to secure the assembled screen 43 using fasteners 50, 52, e.g. brackets and screws or rivets. The cabinet door 40 also includes mounting brackets 54, 56, e.g. door hinges, that can be used to mount the cabinet door to a cabinet base. The cabinet door 40 may also include bumpers 58, 60 made of plastic or rubber adhesively fixed to a peripheral of the side wall 44. The bumpers 58, 60 being used to cushion the cabinet door 40 against the cabinet base when opening and closing. In addition, the support frame 42 may include an interior divider wall 62, 64 along the peripheral sides of the sidewall 44 that separates the interior of the support frame 42 into a spacer area for cushioning the display screen 43 and a divider section that can be used to mount the door handle and hinges. Finally, the display screen 43 includes at least a High-Definition Multimedia Interface (HDMI) 68 and a Universal Serial Port (USB) 66. The interfaces allow for a connection from a central service application server and, in the case of wireless, allows for the power supply to the HDMI 68.

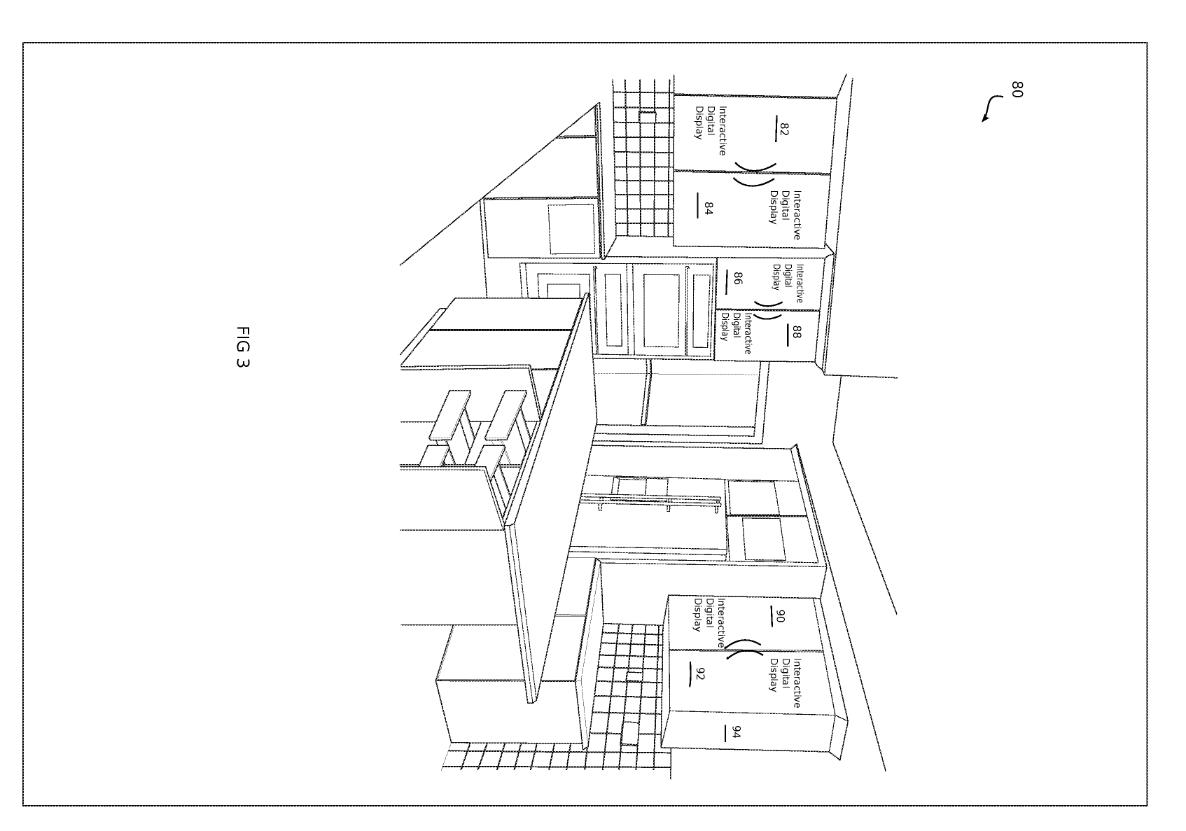

Referring now to FIG. 3, illustrated is an exemplary view of a cabinet base system that utilizes interactive cabinet doors, e.g. in a home kitchen, denoted generally as 80. The system 80 includes interactive cabinet doors 82, 84, 86, 88, 90, 92 constructed as previously discussed in reference to FIGS. 1 and 2. The cabinet doors 82-92 can be communicable coupled with remote application service system vis a vi a router, for example, a cable set-top box, or many other options available in the market, preferable via a wireless connection, e.g. over a HDMI wireless interface. The cabinet doors 82-92 are physically attached to their respective cabinet bases, e.g. cabinet base 94. The cabinet doors 82-92 allows the consumer to be digitally and interactively connected throughout the home.

Although specific embodiments have been described above in detail, the description is merely for purposes of illustration. It should be appreciated, therefore, that many aspects described above are not intended as required or essential elements unless explicitly stated otherwise. Modifications of, and equivalent components or acts corresponding to, the disclosed aspects of the example embodiments, in addition to those described above, can be made by a person of ordinary skill in the art, having the benefit of the present disclosure, without departing from the spirit and scope of embodiments defined in the following claims, the scope of which is to be accorded the broadest interpretation so as to encompass such modifications and equivalent structures.

1. An interactive cabinet door for use with a cabinet base, the cabinet door comprising:
a protective glass cover;
an electronic display adhesively coupled with the protective glass cover;
a Printed Circuit Board (PCB) substrate electronically and adhesively coupled with the electronic display;
a support frame surrounding the protective glass cover, the electronic display, and the PCB substrate;
multiple support brackets fixed to the support frame along a peripheral back side of the support frame and mountable with the cabinet base; and
a handle fixed to the support frame along a peripheral front side of the support frame.

2. The cabinet door of claim 1 further comprising at least one plastic bumper along another peripheral back side of the support frame

3. The cabinet door of claim 1 wherein the protective glass is made from alkali-aluminosilicate.

4. The cabinet door of claim 1 wherein the protective glass cover is adhesively coupled using an epoxy.

5. The cabinet door of claim 1 wherein the support frame surrounding the glass cover, the electronic display, and the PCB substrate is adhesively bonded with the glass cover and the PCB substrate.

6. The cabinet door of claim 1 wherein the support frame surrounding the glass cover, the electronic display, and the PCB substrate further includes:
a front support frame;
a back support frame; and
the front support bracket and the back support bracket are physically coupled using at least one of an adhesive bond and a coupling bracket.
